(19) United States
(12) Patent Application Publication
(10) Pub. No.: US 2007/0148492 A1
(43) Pub. Date: Jun. 28, 2007

(54) LIGHT-EMITTING DEVICE

(75) Inventors: Akira Tsuboyama, Tokyo (JP); Kazunori Ueno, Ebina-shi (JP); Satoshi Igawa, Fujisawa-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/613,439

(22) Filed: Dec. 20, 2006

(30) Foreign Application Priority Data
Dec. 22, 2005 (JP) 2005-370170

(51) Int. Cl. H01L 51/54

(52) U.S. Cl. 428/690; 428/917; 313/504; 313/506; 257/89; 257/E51.044

(57) ABSTRACT

A light emitting device includes a plurality of luminescent materials, two of the plurality of luminescent materials being phosphorescent materials producing phosphorescence from the MLCT excited state.

### BACKGROUND OF THE INVENTION

1. Field of the Invention

The present invention relates to a light emitting device using an organic compound, and particularly to a light emitting device using a phosphorescent metal coordination compound as a luminescent material for improving luminous efficiency and color reproducibility.

2. Description of the Related Art

Organic electroluminescence (EL) devices have been energetically researched for use as light emitting devices with rapid response and high luminous efficiency (Macromol. Symp., 1997, 125, 1-48). In particular, phosphorescent metal coordination compounds have been widely studied as luminescent materials used for organic EL devices in view of their high luminous efficiency and stability (Inorganic Chemistry 2001, 40, 1704-1711, Journal of American Chemical Society, 2001, 123, 4304-4312, WO02/44189, and WO03/91355).

Phosphorescent EL devices using phosphorescent metal coordination compounds exhibit a problem because of decreased EL efficiency when high-density current is applied (Journal American Chemical Society, 2001, 123, 4304-4312). FIGS. 1A and 1B show an actual example of the problem (Journal of American Chemical Society, 2003, 125, 12971-12979). FIG. 1A shows the relation of current density to voltage and FIG. 1B shows the relation of power efficiency (Im/W) and external quantum efficiency (%) to luminance of an EL device using Ir(piq)3 (R1 shown in FIG. 2) as a luminescent material. FIG. 1B reveals that the EL efficiencies significantly decrease in a high-luminance region. The decrease in efficiency at high luminance is due to a quenching phenomenon referred to as “triplet-triplet (TT) annihilation”. This phenomenon is described in detail in Physical Review B, 2000, 62, 10967-10977. According to this document, a current density J₀, where EL quantum efficiency η is halved in a region without TT annihilation, is represented by the following equation:
J₀ ∞(1/τ)²
wherein τ is the phosphorescence lifetime of a phosphorescent dopant. The half-quantum efficiency current density J₀, where EL quantum efficiency η is halved, basically decreases in inverse proportion to the square of phosphorescence lifetime. Therefore, a dopant with a long phosphorescence lifetime τ has a low half-quantum-efficiency current density J₀, while a dopant with a short phosphorescence lifetime τ has a high half-quantum-efficiency current density J₀. Quantitatively, the density of triplet excitons recombined in a luminescent layer increases as the current density increases. When the density of triplet excitons increases, the probability of TT annihilation increases, and thus the luminous efficiency at a high current density significantly decreases.

This becomes a large problem when a plurality of phosphorescent materials is used to simultaneously emit light and develop many colors by color mixing. The phosphorescence lifetime generally depends on the phosphorescent material used. For example, when white luminescence is produced by RGB color mixing of phosphorescent materials having different phosphorescence lifetimes, a change in white luminance undesirably causes a color shift due to a difference in applied current dependence between luminous efficiencies of respective colors. In order to prevent a color shift, luminance can be corrected by a driver element for applying a current according to the luminous efficiency. However, incorporating a correction circuit increases costs, and a development load is required for developing software to operate the correction circuit, thereby reducing productivity.

In Advanced Materials 2002, 14, 147-151 and Advanced Materials 2004, 16, 624-628, an EL device using a plurality of phosphorescent materials to develop white color by color mixing has been proposed. FIG. 2 shows examples of typical phosphorescent materials including phosphorescent iridium complexes used in Advanced Materials 2002, 14, 147-151 and Advanced Materials 2004, 16, 624-628. FIG. 2 is a table showing phosphorescent materials divided into RGB groups. In FIG. 2, MLCT and π-π* represent the types of luminescent excited states. These types will be described below.

In Advanced Materials 2002, 14, 147-151, B1, G4, and R5 shown in FIG. 2 are used as luminescent materials to form a white light emitting element. In Advanced Materials 2004, 16, 624-628, B2, G1, and R7 shown in FIG. 2 are used as blue, green, and red luminescent materials, respectively. In Advanced Materials 2004, 16, 624-628, a color shift due to the applied current is described. Although the color shift is possibly due to multiple factors, a large factor is the above-described difference in current dependence between the luminous efficiencies of respective colors due to TT annihilation.

The phosphorescence lifetime significantly depends on the electron state in a phosphorescent excited state. It is known that among excited states of metal coordination compounds, luminescence from the MLCT excited state and π-π* excited state has the highest intensity at room temperature. The MLCT excited state is an abbreviation of a metal-to-ligand charge transfer state which is formed by transfer of electrons of a center metal of a metal coordination compound to a ligand. On the other hand, the π-π* excited state is mainly caused by a ligand, i.e., formed by π-to-π* excitation transfer of a ligand. Journal of American Chemical Society, 2003, 125, 12971-12979 discloses that the MLCT excited state exhibits higher luminous efficiency and shorter phosphorescence lifetime. The phosphorescence lifetime τ is represented by the following equation:
τ=1/(kr+knr) (2)
wherein kr and knr are a radiation rate constant and a non-radiation rate constant, respectively. A metal coordination compound which produces luminescence from the MLCT excited state generally has a higher kr value than that from the π-π* excited state, and accordingly, τ is decreased. Furthermore, the luminous efficiency φis represented by the following equation (3):
φ=kr/(kr+knr)=τ·kr (3)

### SUMMARY OF THE INVENTION

The present invention provides a light emitting device including a light emitting device having high luminous efficiency and low cost and causing no color shift due to a change in luminance.

Therefore, the present invention provides a light emitting device in which light is emitted from a plurality of luminescent materials of different colors, two or more of the luminescent materials are phosphorescent metal coordination compounds, and the two or more phosphorescent metal coordination compounds are compounds which produce phosphorescence from the MLCT excited state.

Further features of the present invention will become apparent from the following description of exemplary embodiments with reference to the attached drawings.

### BRIEF DESCRIPTION OF THE DRAWINGS

FIGS. 1A and 1B are graphs each showing known changes in EL luminous efficiency when high-density current is applied.

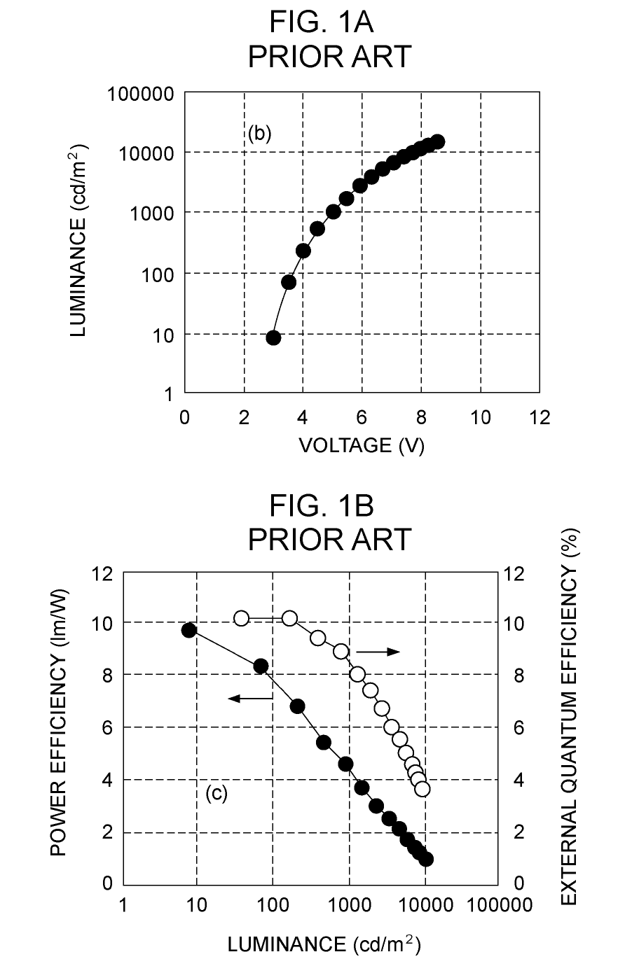

FIG. 2 is a table showing structural formulae of known metal coordination compounds.

FIGS. 3A and 3B are emission spectra of compounds G1 and G4, respectively.

FIG. 4 is a drawing showing the skeletons of other compounds used in a light emitting device.

FIG. 5 is a graph based on the results shown in Table 2.

### DESCRIPTION OF THE EMBODIMENTS

The present invention will be described in detail below.

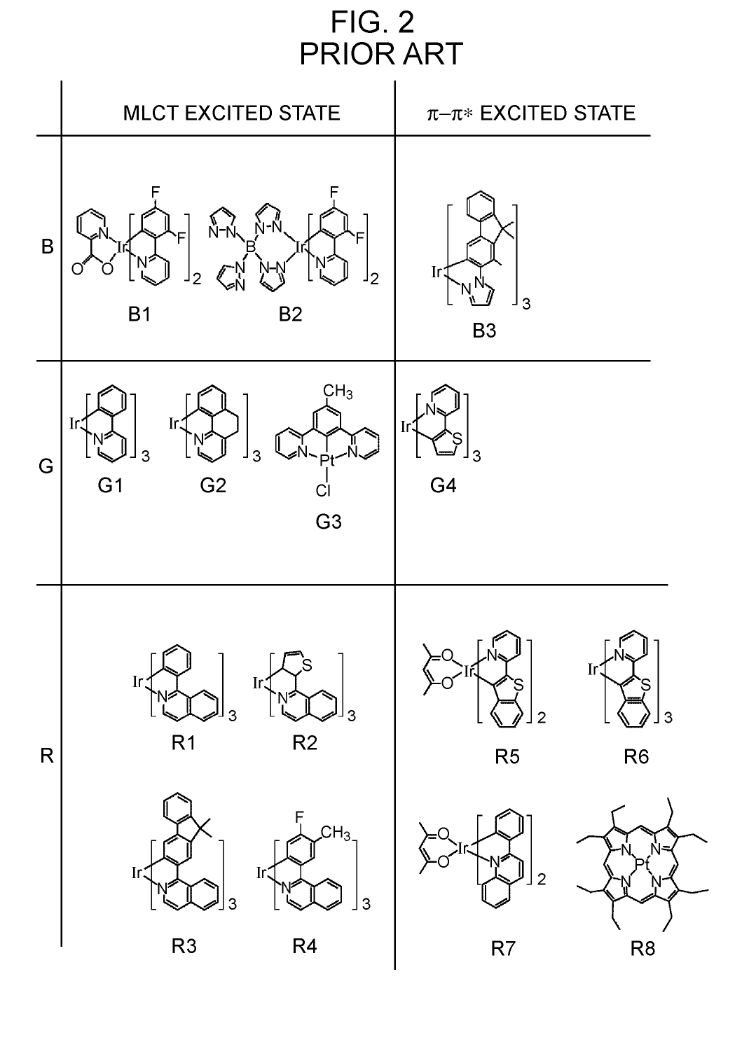

FIG. 2 shows typical examples of phosphorescent materials (phosphorescent metal coordination compounds). In the table of FIG. 2, RGB in a column represent red, green, and blue colors, respectively, and MLCT and π-π* in a line represent the respective phosphorescent excited states of luminescent materials. The classification of these excited states is described in Journal of American Chemical Society, 2001, 123, 4304-4312 and Journal of American Chemical Society, 2003, 125, 12971-12979. Table 1 which follows shows the phosphorescence lifetimes (τ) in a toluene solution at room temperature, luminescent quantum yields (φ), radiation rate constants (kr), non-radiation rate constants (knr), and lowest luminescent excited states of the luminescent materials shown in FIG. 2.

TABLE 1

| | τ | φ | kr/10⁵ | knr/10⁵ | Lowest excited state |
|---|---|---|---|---|---|
| B1 | 1.5 | 0.6 | 4.0 | 2.7 | MLCT |
| B2 | 3.7 | 0.73 | 2.0 | 0.7 | MLCT |
| B3 | 37.0 | 0.38 | 0.1 | 0.2 | π—π* |
| G1 | 2.0 | 0.4 | 2.0 | 3.0 | MLCT |
| G2 | 1.3 | 0.45 | 3.5 | 4.2 | MLCT |
| G3 | 3.0 | 0.5 | 1.7 | 1.7 | MLCT |
| G4 | 2.4 | 0.17 | 0.7 | 3.5 | π—π* |
| R1 | 0.7 | 0.26 | 3.7 | 10.6 | MLCT |
| R2 | 0.7 | 0.17 | 2.4 | 11.9 | MLCT |
| R3 | 0.7 | 0.19 | 2.7 | 11.6 | MLCT |
| R4 | 1.7 | 0.32 | 1.9 | 4.1 | MLCT |
| R5 | 5.8 | 0.21 | 0.4 | 1.4 | π—π* |
| R6 | 4.0 | 0.12 | 0.3 | 2.2 | π—π* |
| R7 | 2.0 | 0.1 | 0.5 | 4.5 | π—π* |
| R8 | 40 | 0.5 | 0.13 | 0.13 | π—π* |

The luminescent materials used in the present invention have a luminescent MLCT excited state. The luminescent materials having the MLCT excited state have an elevated value of kr (kr≧1.0×10⁵). Further, luminescent materials having the π-π* excited state have a reduced value of kr (kr≦1.0×10⁵).

In general, kr has substantially no dependence on temperature and an environment in which a compound is placed, but knr is very sensitive to the environment. Since compound molecules freely move in a solution, molecules in an excited state encounter molecules to be quenched, thereby increasing knr. On the other hand, when a phosphorescent compound is dispersed in a solid, compound molecules cannot freely move, thereby decreasing knr. As a result, a non-radiation process is suppressed which increases luminous efficiency in a solid. In fact, Ir(ppy)3 has an efficiency of 0.4 in a solution at room temperature, but a host material solid of, for example, an OLED device, in which this compound is dispersed, exhibits a luminous efficiency close to 1.0. Therefore, in a solution, non-radiant deactivation of the compound readily occurs to increase the value of knr, while in a solid, the knr value of the compound is decreased. Accordingly, kr is basically specific to a compound, but knr greatly depends on the surrounding environment. Therefore, for a solid organic LED device, kr is an important parameter for phosphorescence lifetime.

The metal coordination compounds having the MLCT excited state show higher kr values than those of compounds having the π-π* excited state. The luminescent quantum efficiency φ is determined by a correlation between kr and knr according to equation (3). However, according to Journal of American Chemical Society, 2003, 125, 12971-12979, a phosphorescent material having the MLCT excited state with a large kr generally shows a higher phosphorescent efficiency. When a phosphorescent material exhibiting a high phosphorescent efficiency in a solution is used for an organic EL device, a high EL efficiency can be generally obtained. A phosphorescent material having the MLCT excited state has a high kr and thus has a short phosphorescence lifetime τ (equation 2). Thus, the half-quantum-efficiency current density represented by equation 1 is increased, thereby achieving high efficiency in a wide luminous range.

In a light emitting device using a plurality of phosphorescent materials, when luminescence by color mixing is used, the half-quantum-efficiency current densities J₀ of phosphorescent materials of respective colors are preferably substantially the same in order to decrease the luminance dependence of color purity. In addition, it has been found that the kr ratio between phosphorescent materials is an important parameter for decreasing the luminance dependency of color. Accordingly, it is of practical importance that the maximum ratio between the kr values of phosphorescent materials used is 3 or less. Therefore, it was found that in order to obtain a light emitting device with high efficiency and a small color shift due to a change in luminance, it is important to use a plurality of phosphorescent materials producing luminescence from the MLCT excited state and to set the ratio between the radiation rate constants of phosphorescent materials used to 3 or less.

Whether luminescence arises from the MLCT excited state or the π-π* excited state is determined on the basis of the following items as the characteristics of phosphorescence from the MLCT excited state:
kr>1.0×10⁵ s⁻¹ (1)

(2) An emission spectrum is broad and shows a single peak, and thus a vibration structure (spectrum peaks resulted from a vibration mode) is unclear.

A kr value can be calculated from equations (2) and (3) using the phosphorescent efficiency and phosphorescence lifetime measured in a solution at room temperature. As a solvent of the solution, a solvent which dissolves phosphorescent compounds, such as toluene, chloroform, 0, m, or p-xylene, or chlorobenzene, may be used. Since phosphorescence is generally quenched by oxygen, the solvent is carefully subjected to argon or nitrogen in order to remove oxygen from the solvent.

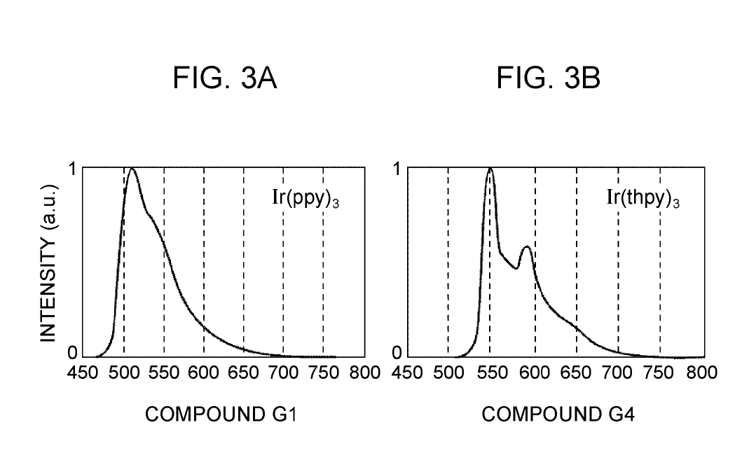

FIGS. 3A and 3B show emission spectra of compounds G1 and G3, respectively. Compound G1 shows a broad emission spectrum having one emission peak. On the other hand, compound G3 shows two clear emission peaks each having a small band width. The sub-peaks correspond to vibrational levels of the ground state. The emission band width reflects the magnitude of dipole in an excited state. The dipole in an MLCT excited state is relatively large because of the charge movement in MLCT excitation transition, and thus the spectrum band width of an emission spectrum becomes broad due to an interaction with surrounding solvent molecules. On the other hand, for emissions from the π-π* excited state, the dipole in the excited state is substantially the same as that in the ground state. Therefore, the dipole in the excited state is relatively small, and the band width is also small due to small interaction with solvent molecules. A small band width causes a clear vibration structure (spectrum peaks resulting from a vibration mode) to appear.

Whether a compound exhibits the MLCT excited state can be determined by measuring an emission spectrum and phosphorescence lifetime in a solution. Both or one of the items (1) and (2) may be satisfied.

Phosphorescence produced from the MLCT excited state is characterized by a large radiation rate constant and high luminous efficiency. The radiation rate constant kr of luminescence from the MLCT excited state is larger than that from the π-π* excited state.

When the non-radiation rate constant knr in a solid is sufficiently suppressed, the phosphorescence lifetime τ is the reciprocal of the radiation rate constant kr according to equation (2). The half-quantum-efficiency current density J₀ is inversely proportional to the square of τ.

When the half-quantum-efficiency current densities J₀ of luminescent colors are substantially the same, a color shift depending on luminance is insignificant, and an OLED device with no practical problems can be achieved.

Therefore, when an OLED device is formed by a combination of two or more phosphorescent materials, a light emitting device with high luminous efficiency and no color shift can be realized by selecting phosphorescent materials having a luminescent excited state with kr>1.0×10⁵ s⁻¹ in the MLCT excited state.

The inventors further found that even in an OLED device causing color mixing by a phosphorescent material and a fluorescence material, when a phosphorescent material producing phosphorescence from the MLCT excited state is used, the device with high efficiency and no color shift due to luminance can be obtained.

The radiation rate constant kr of luminescence of a fluorescent material is about 10⁸ to 10⁹ s⁻¹ and is significantly higher that those of general phosphorescent materials. When a combination of a fluorescent material and a phosphorescent material is used for a device, by using a phosphorescent material having a high radiation rate constant and producing luminescence from the MLCT excited state, a high-quality device with no color shift can be produced. As a result of further research, it was found that when a combination of a fluorescent material and a phosphorescent material is used, a light emitting device, such as a high-quality display or illumination, which has high efficiency and no color shift due to luminance dependency, can be produced using a phosphorescent material having a radiation rate constant kr of >1×10⁵.

The present invention is not limited to a light emitting device which emits white light by color mixing using a plurality of luminescent colors for one OLED element. For example, when an OLED device is used for a display, a method of providing RGB light emitting elements in respective pixels to display a desired image is frequently used. In this embodiment, when respective pixels have different half-quantum-efficiency current densities J₀ represented by equation (1), then it is necessary to strictly control the current value applied to each of the pixels, thereby increasing the cost. In the present invention, by using a luminescent material having the MLCT phosphorescent excited state, it is possible to provide a high-quality display having substantially same J₀ and substantially no color shift.

Illustrative Examples will be described below. Examples 1 to 3 and Comparative Examples 1 to 3

All the compounds employed, other than luminescent compounds, are the same in Examples 1 to 3 and Comparative Examples 1 and 3.

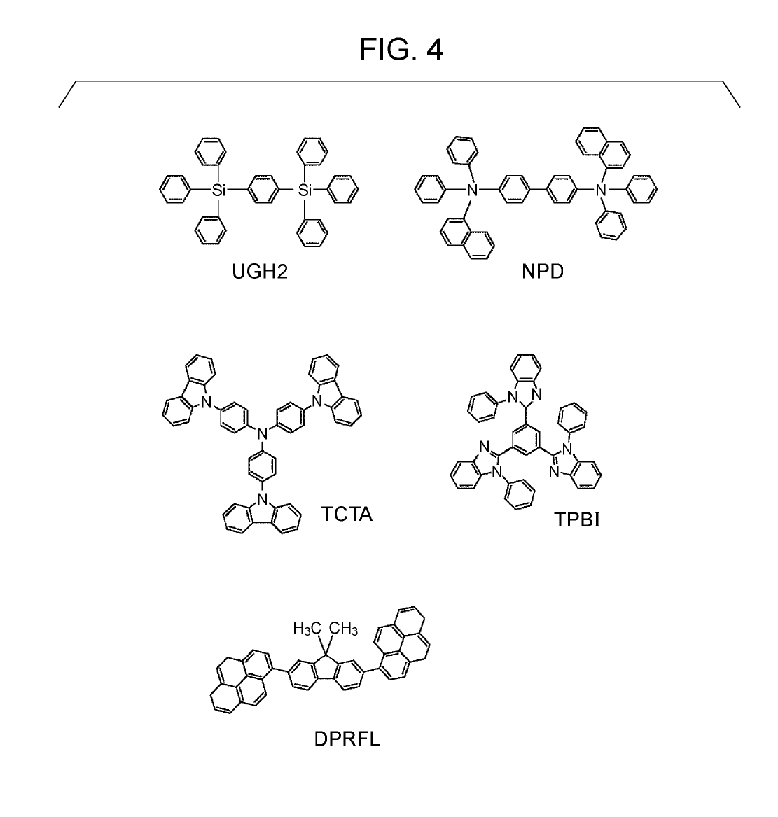

The compounds used in an element produced are shown in FIG. 4.

Transparent electrode (100 nm): ITO

Hole injection layer (30 nm): NPD

Hole transport layer (20 nm): TCTA

Luminescent layer (40 nm): host material: UGH4+luminescent material

Electron transport layer (30 nm): TPBI

Electron transport material (5 nm): lithium fluoride

Cathode (100 nm): aluminum

NPD: p-bis(.-naphtylphenylamino)biphenyl

TCTA: 4,4′,4″-tri(N-carbazolyl)triphenylamine

UGH4: p-bis(triphenylsilyl)benzene

TPBI: 1,3,5-tris(N-phenylbenzimidazol-2-yl)benzene

The luminescent compounds used are shown in FIG. 2 as follows:

Example 1: (2%, B1) (1%, G1) (15%, R1) [maximum kr ratio=2.0]

Example 2: (2%, B1) (1%, G2) (15%, R1) [maximum kr ratio=1.14]

Example 3: (2%, B2) (1%, G1) (15%, R4) [maximum kr ratio=1.05]

Comparative Example 1: (2%, B1) (1%, G1) (15%, R8) [maximum kr ratio=30]

Comparative Example 2: (2%, B1) (1%, G3) (15%, R6) [maximum kr ratio=13.3]

Comparative Example 3: (2%, B1) (1%, G3) (15%, R7) [maximum kr ratio=3.4]

Each of these elements was formed by a vacuum deposition method, and a luminescent layer was formed by a codeposition method of simultaneously depositing four materials.

Table 2 shows the CIE xy-color coordinate values of each element at each applied current value. Table 2 indicates the following: When phosphorescent materials producing phosphorescence from the MLCT excited state are used as three luminescent materials of RGB as in Examples 1 to 3, a color shift is very small and only about 0.02. However, when a luminescent material producing luminescence from the π-π* excited state is included in the three luminescent materials of RGB as in Comparative Examples 1 to 3, a color shift is as large as 0.08 or more, thereby causing a practical problem. The element using phosphorescent materials producing phosphorescence from the MLCT excited state as three luminescent materials of RGB has only a small dependency of color on luminance and has excellent performance. It is also found that the elements of Examples 1 to 3 have a luminous efficiency twice as high as those of Comparative Examples 1 and 3 at the applied current of 5 mA/cm². From this viewpoint, the elements of Examples 1 to 3 are excellent in performance.

TABLE 2

| | | | | Luminous |
|---|---|---|---|---|
| | | | | efficiency |
| | 0.1 mA/cm² | 1 mA/cm² | 5 mA/cm² | cd/A |
| Example 1 | (0.43, 0.41) | (0.42, 0.40) | (0.41, 0.40) | 8.5 |
| Example 2 | (0.39, 0.40) | (0.39, 0.41) | (0.38, 0.40) | 11.0 |
| Example 3 | (0.40, 0.41) | (0.39, 0.41) | (0.39, 0.40) | 9.2 |
| Comp. Example 1 | (0.38, 0.43) | (0.36, 0.39) | (0.35, 0.38) | 4.0 |
| Comp. Example 2 | (0.38, 0.33) | (0.35, 0.33) | (0.31, 0.32) | 4.8 |
| Comp. Example 3 | (0.35, 0.35) | (0.34, 0.37) | (0.32, 0.41) | 3.5 |

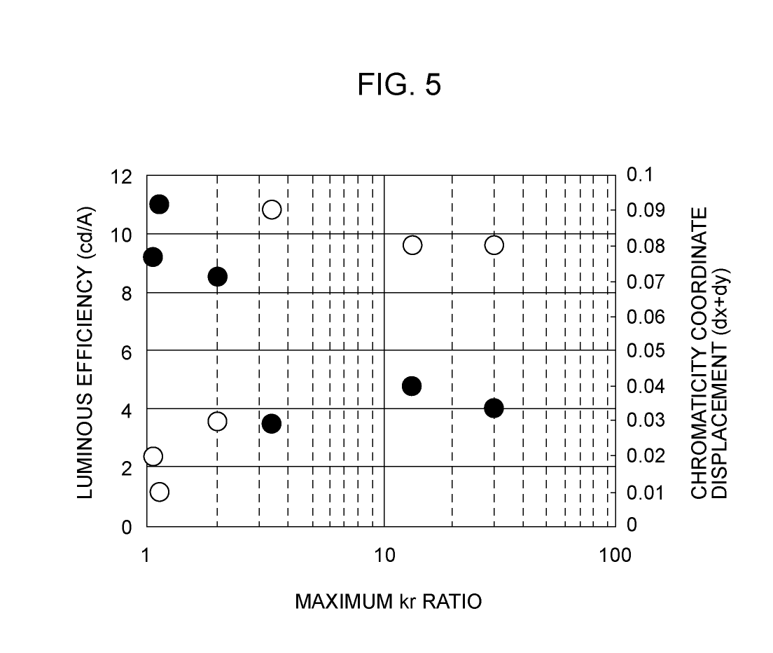

FIG. 5 is a graph showing the results shown in Table 2. In FIG. 5, the maximum kr ratio of radiation rate constants kr of luminescent materials used in an element is shown as the abscissa, and the luminous efficiency and the total of color coordinate displacements are shown as ordinates. FIG. 5 indicates that in an element using a MLCT phosphorescent material of the present invention, when the maximum kr ratio is 3 or less, a color displacement is sufficiently suppressed.

In each of the examples, a plurality of phosphorescent materials used for an element of the present invention produces luminescence from the MLCT excited state. In an element of the present invention, high luminous efficiency can be obtained because the radiation rate constant kr was 1×10⁵ s⁻¹ or more. In addition, when the maximum kr ratio between the phosphorescent materials used in an element of the present invention is 3 or less, a color shift due to a luminance change can be suppressed, and thus a light emitting device with high efficiency and no color Shift can be provided.

### EXAMPLES 4 AND 5 AND COMPARATIVE EXAMPLE 3

In these examples, an OLED device was formed by providing emission regions in respective RGB pixels. A fluorescent material DPRFL was used in B pixels, and a phosphorescent material was used in GR pixels.

The constitution of an element was as follows:

Blue Pixel:
Transparent electrode (100 nm): ITO
Hole transport layer (20 nm): FL01
Luminescent layer (40 nm): DPRFL
Electron transport layer (30 nm): BCP
Electron transport material (5 nm): lithium fluoride
Cathode (100 m): aluminum
FL01: 4,4′-bis-(2-fluorenylphenylamino)biphenyl
DPRFL: 2,7-bis-(2-pyrenyl)fluorine

Green Pixel and Red Pixel
Transparent electrode (100 nm): ITO
Hole transport layer (20 nm): FL01
Luminescent layer (40 nm): CBP host+10% luminescent material
Electron transport layer (30 nm): BCP
Electron transport material (5 nm): lithium fluoride
Cathode (100 nm): aluminum
DPRFL used in blue pixels was a fluorescent material.

Green and red pixels were phosphorescent elements having a common element constitution and using the following luminescent materials:

Example 4→(green phosphorescent material=G1, red phosphorescent material=R1) [maximum kr ratio=1.9]

Example 5→(green phosphorescent material=G2, red phosphorescent material=R1) [maximum kr ratio=1.05]

Comparative Example 4→(green phosphorescent material=G2, red phosphorescent material=R7) [maximum kr ratio=27]

TABLE 3

| | | | Luminous |
|---|---|---|---|
| | 1 mA/cm² | 5 mA/cm² | efficiency |
| Example 4 | (0.33, 0.35) | (0.33, 0.35) | 4.2 cd/A |
| Example 5 | (0.37, 0.35) | (0.37, 0.34) | 5.0 cd/A |
| Comp. Example 4 | (0.36, 0.35) | (0.38, 0.32) | 2.1 cd/A |

Table 3 shows CIE chromaticity obtained by applying a current. The current ratio between pixels was controlled so that chromaticity at the applied current of 1 mA/cm² was as shown in Table 3. Then, the current applied to each pixel was linearly increased while maintaining the ratio to measure chromaticity at 5 mA/cm². In Examples 4 and 5, the values of chromaticity at 1 mA/cm² and 5 mA/cm² were substantially the same, while in Comparative Example 3, chromaticity was greatly changed. Also, the luminous efficiencies in Examples 4 and 5 were as high as at least twice that of Comparative Example 3.

It was also found that even when a luminescent color is obtained by color mixing using a combination of a phosphorescent material and a fluorescent material, a light emitting element with no color shift and high efficiency can be produced using a plurality of phosphorescent materials producing phosphorescence from the MLCT excited state.

These examples show that even when a combination of a fluorescent material and a plurality of phosphorescent materials is used, by using a plurality of phosphorescent material having the MLCT phosphorescent excited state, a color shift due to a change in luminance can be suppressed, and a light emitting device with high efficiency and no color shift can be provided. Specifically, it was found that high luminous efficiency is obtained due to a radiation rate constant kr of 1×10⁵ s⁻¹ or more. It was further found that when the maximum kr ratio between phosphorescent materials is 3 or less, a color shift due to a change in luminance can be suppressed, and a light emitting device with high efficiency and no color shift can be provided.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

This application claims the benefit of Japanese Application No. 2005-370170 filed Dec. 22, 2006, which is hereby incorporated by reference herein in its entirety.

What is claimed is:

1. A light emitting device comprising a plurality of luminescent materials developing different colors;
wherein two or more of the luminescent materials are phosphorescent metal coordination compounds; and
the two or more phosphorescent metal coordination compounds produce phosphorescence from a MLCT excited state.

2. The light emitting device according to claim 1, wherein a maximum ratio between radiation rate constants of the two or more phosphorescent metal coordination compounds is 3 or less.

3. The light emitting device according to claim 1, wherein radiation rate constants of the two or more phosphorescent metal coordination compounds are more than 1×10⁵ s⁻¹.

4. The light emitting device according to claim 1, wherein three or more luminescent materials are used, and all the luminescent materials are phosphorescent metal coordination compounds.

5. The light emitting device according to claim 1, wherein three or more luminescent materials are used, and one of the three or more luminescent materials is a fluorescent compound, the remaining luminescent materials being phosphorescent metal coordination compounds.

6. The light emitting device according to claim 1, wherein the phosphorescent metal coordination compounds are iridium complexes.

7. The light emitting device according to claim 1, wherein the phosphorescent metal coordination compounds are platinum complexes.

8. The light emitting device according to claim 1, comprising a light emitting element;
wherein all the two or more phosphorescent metal coordination compounds are contained in the same luminescent layer, and the light emitting element includes at least the luminescent layer and a pair of electrodes holding the luminescent layer therebetween.

9. The light emitting device according to claim 1, comprising a plurality of light emitting elements each including at least a luminescent layer and a pair of electrodes holding the luminescent layer therebetween;
wherein the plurality of light emitting elements have the luminescent materials developing different colors.

10. A display device comprising the light emitting device according to claim 1.
